(19) United States
(12) Patent Application Publication
(10) Pub. No.: US 2013/0170108 A1
(43) Pub. Date: Jul. 4, 2013

(54) HINGE AND ELECTRONIC DEVICE WITH THE HINGE

(71) Applicant: Le-Yao LIN, New Taipei City (TW)

(72) Inventor: Le-Yao LIN, New Taipei City (TW)

(21) Appl. No.: 13/343,321

(22) Filed: Jan. 4, 2012

(51) Int. Cl. H05K 7/00; E05D 3/12

(52) U.S. Cl. 361/679.01; 16/366

(57) ABSTRACT

A hinge comprises a twin-shaft body, a first shaft, a first connecting part, a second shaft, and a second connecting part: the twin-shaft body is designed to have mounting holes on its both sides for the holes securely inserted into the first shaft and the second shaft which are coupled with the first connecting part and the second connecting part separately for the connecting parts turning around the shafts and turning angles restricted by two pairs of retainers and stoppers, each of which is designed on one shaft and one connecting part, respectively; the first connecting part is effective in enabling rotation of an electronic device's first device body which turns to a specific angle and drive the twin-shaft body to turn around the second shaft for the electronic device's first device body over the second device body.

### BACKGROUND OF THE INVENTION

a) Field of the Invention

The present invention relates to one hinge and one electronic device with the hinge, especially one hinge applied to supports on the electronic device for any turning angle freely adjusted and increased to a larger one.

b) Description of the Prior Art

The evolution of computer developed to be a portable device has unexceptionally prompted all manufacturers to produce portable computers being available at all times and based on some indispensable factors such as durable electricity and computational efficiency which depend on power-saving elements and high-capacity batteries developed by semiconductor and battery manufacturers, respectively.

On the other hand, the mechanism for one computer without limitation of any occasion relies on a system manufacturer's design, for instance, an existing foldable notebook computer has twin pieces, one computer screen and one keyboard installed on two single pieces and constituting a foldable structure with an included angle of 90 degrees approximately, and is placed on one desk for convenient use but unfavorable to handheld operation.

The resolution herein is based on a tablet PC (Personal Computer) on which there is one display designed for a user's one hand holding the computer and other unoccupied hand manipulating a touch pen to click on functional keys or to write something on the touch panel.

In view of one computer for critical accesses completed by entering texts, a touch pen as one major means of a tablet PC operated on one palm for texts entered is a slow and hard-to-use tool compared with a keyboard and restricts or deteriorates convenience during texts entered into a computer despite its significant improvement in portability and convenience. Accordingly, the perspective of tablet PCs is not optimistic according to lots of persons' opinions and theses machines have been applicable to some specific purposes only, for instance, options checked by a physician visiting wards or a warehouseman making an inventory, except for texts entered.

To solve the problem of texts difficulty entered onto a tablet PC, some models are provided with a fanwise keypad designed on a touch panel and clicked on by two thumbs of one user holding a computer by hands. However, the speed to operate the computer by thumbs is much slower than that of operating another computer by a physical keyboard owing to the restricted extent of moving thumbs of two hands used to hold the computer as well as intrinsic insensitivity of thumbs.

Another design is a physical slip keypad which is ordinarily concealed inside and slipped outward for lots of texts to be entered. Like a keypad on a touch panel, this mechanism, however, needs fingers to hold a computer except insensitive thumbs which are used to operate the keypad and exhausts a holder whose hands operate the keypad and strenuously sustain a computer with its center of gravity out of hands due to a display extended backward.

Accordingly, the issue to change the structural design of one electronic device such as notebook computer and transfer a notebook computer as one tablet PC for use has become an urgent topic.

### SUMMARY OF THE INVENTION

The object of the present invention is to provide a hinge for any turning angle freely adjusted and increased to a larger one.

The other object of the present invention is to provide one electronic device equipped with one hinge for any turning angle freely adjusted and increased to a larger one.

To deliver the two said objects, the present invention embodied by the following measures comprises a twin-shaft body, a first shaft, a first connecting part, a second shaft and a second connecting part for the first connecting part and the second connecting part fixed on an electronic device: the twin-shaft body provided with mounting holes on its both sides for both the first shaft and the second shaft to be inserted and fixed; the first shaft and the second shaft coupled with the first connecting part and the second connecting part, respectively, each of which turns around one corresponding shaft but allows its turning angle to be restricted by a retainer and a stopper arranged between a shaft and a connecting part.

To deliver the other object previously described, the electronic device in the present invention comprises a first device body and a second device body, supports for the device bodies installed inside and a hinge previously described. The hinge fixed on the supports is effective in turning both the first device body and the second device body around the hinge and an electronic device's first device body over the second device body via the first shaft and the second shaft coordinated each other.

To enable a further understanding of the said objectives and the technological methods of the invention herein, the brief description of the drawings below is followed by the detailed description of the preferred embodiments.

### BRIEF DESCRIPTIONS OF THE DRAWINGS

FIG. 1 is the exploded perspective view of the present invention of a hinge.

FIG. 2 is the exploded perspective view of the present invention of a hinge from another angle of view.

FIG. 3 is the perspective view of the present invention of a hinge partially assembled.

FIG. 4 is the perspective view of the present invention of a hinge.

FIG. 5 is the perspective view of the present invention of an electronic device.

FIG. 5A is the perspective view of the present invention of an electronic device (FIG. 5) partially magnified.

FIG. 6 illustrates the present invention of an electronic device with its screen opened to the first angle.

FIG. 7 illustrates the present invention of an electronic device with its screen opened to the second angle.

FIG. 8 illustrates the present invention of an electronic device totally turned.

### DETAILED DESCRIPTIONS OF THE PREFERRED EMBODIMENTS

For objects, characteristics, and advantages of the present invention obviously and easily understood, the preferred embodiments along with drawings are particularly interpreted hereinafter.

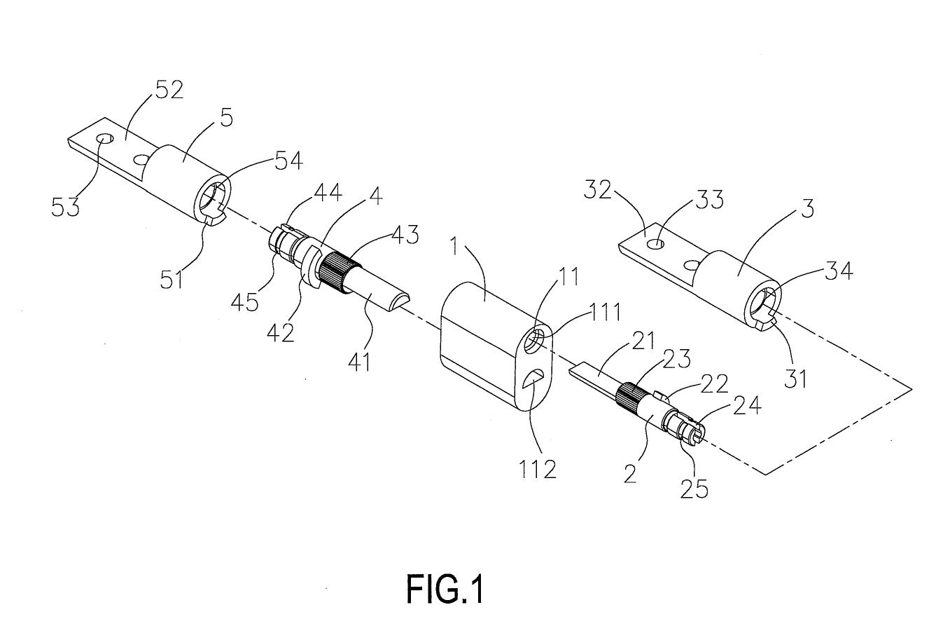

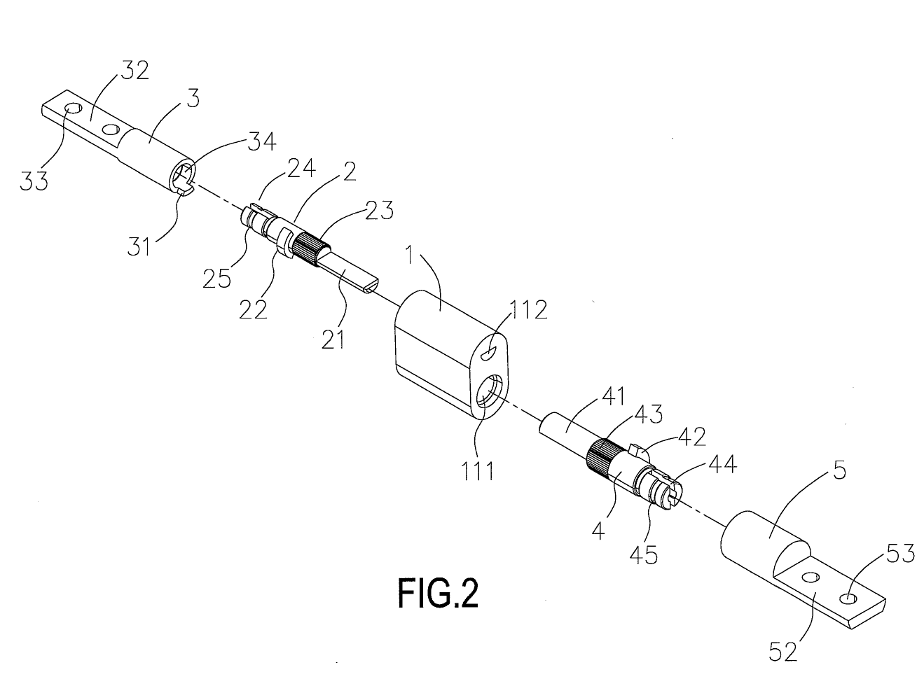

Referring to FIG. 1 and FIG. 2 which illustrate exploded perspective views of the present invention of one hinge comprising a twin-shaft body 1, a first shaft 2, a first connecting part 3, a second shaft 4 and a second connecting part 5;

The rectangle-like twin-shaft body 1 is designed to have mounting holes 11 at its both sides separately and the mounting hole 11 has a ladder-shaped structure with a deformed mounting hole 111 and a pilot hole 112 interlinking the deformed mounting hole 111;

The first shaft 2 which is a cylinder in general has a semi-cylinder locator 21 at one end, a retainer 22 approximately cambered which protrudes outward from the first shaft and combines the first shaft 2 to become a one-piece structure or is mounted on the first shaft 2 via an assembly process, a check surface 23 developed between the retainer 22 and the locator 21, a pivot part 24 formed at the first shaft's other side and opposite to the retainer 22, and a plurality of lubricant grooves 25 on the pivot part 24 for lubricant accommodated;

The first connecting part 3 with one end developed to be a sleeve in which there is a pivot hole 34 is coupled with the pivot part 24 of the first shaft 2 by means of the pivot hole 34 and designed to have a stopper 31 being outward and at the circumferential edge for the stopper 31 and the retainer 22 engaged and held each other, a holder 32 extended to the sleeve-like structure's other end, and a plurality of connecting holes 33 on the holder 32 for an electronic device connected;

The second shaft 4 which is a cylinder in general has a semi-cylinder locator 41 at one end, a retainer 42 approximately cambered which protrudes outward from the second shaft and combines the second shaft 4 to become a one-piece structure or is mounted on the second shaft 4 via an assembly process, a check surface 43 developed between the retainer 42 and the locator 41, a pivot part 44 formed at the first shaft's other side and opposite to the retainer 42, and a plurality of lubricant grooves 45 on the pivot parts 44 for lubricant accommodated;

The second connecting part 5 with one end developed to be a sleeve in which there is a pivot hole 54 is coupled with the pivot part 44 of the second shaft 4 by means of the pivot hole 54 and designed to have a stopper 51 being outward and at the circumferential edge for the stopper 51 and the retainer 42 engaged and held each other, a holder 52 extended to the sleeve-like structure's other end, and a plurality of connecting holes 53 on the holder 52 for an electronic device connected.

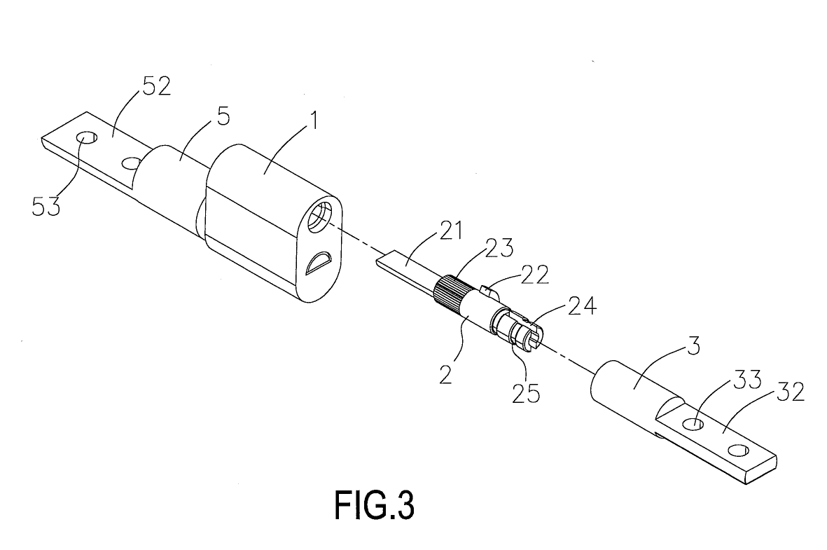

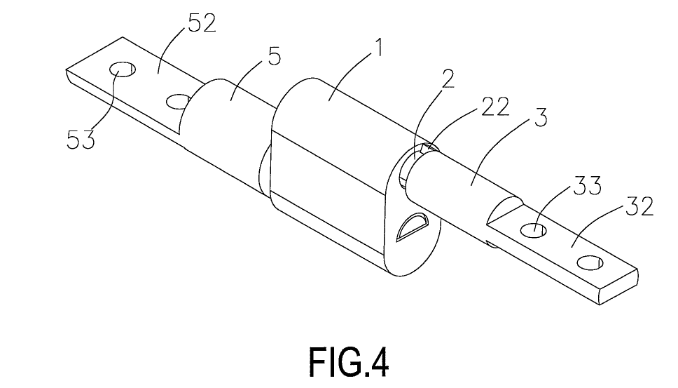

Referring to FIGS. 1, 2, 3 and 4 which illustrate exploded perspective views of the present invention of a hinge partially or completely assembled. For assembly of the present invention, the locator 21 of the first shaft 2 and the locator 41 of the second shaft 4 are inserted into the mounting holes 11 of the twin-shaft body 1 for both the first shaft 2 and the second shaft 4 fixed by means of the pilot holes 112 inside the mounting holes 11 wherein the locator 21 (or the locator 41) and one pilot hole 112 engaged each other are intended for one shaft fixed into but not turned inside the twin-shaft body 1. Furthermore, the check surface 23 on the first shaft 2 (or the check surface 43 on the second shaft 4) engages the mounting hole 11 to make the first shaft 2 (or the second shaft 4) be securely coupled with the mounting hole 11 in the twin-shaft body 1. With the first shaft 2 and the second shaft 4 inserted, the retainers 22 and 42 are exactly adjacent to both sides of the twin-shaft body 1. Then, the first connecting part 3 and the second connecting part 5 engage the pivot part 24 of the first shaft 2 and the pivot part 44 of the second shaft 4, respectively. In virtue of a plurality of lubricant grooves 25 (lubricant grooves 45) on the pivot part 24 (pivot part 44), the first connecting part 3 (second connecting part 5) turns around the pivot part 24 (pivot part 44). With the first connecting part 3 (or the second connecting part 5) coupled with the corresponding shaft, the stopper 22 (or the stopper 42) and the retainer 31 (or the retainer 51) are mutually engaged and held to prevent any improper movement and make sure of a limited turning angle.

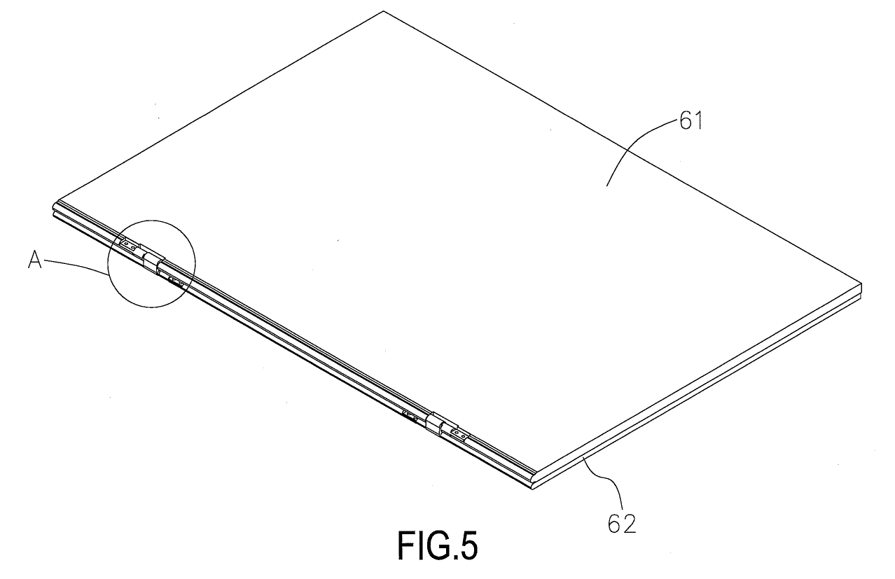

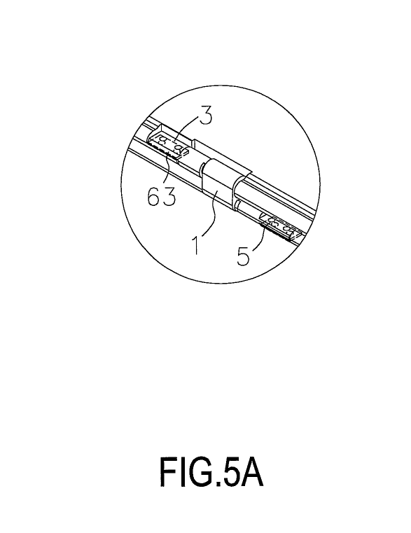

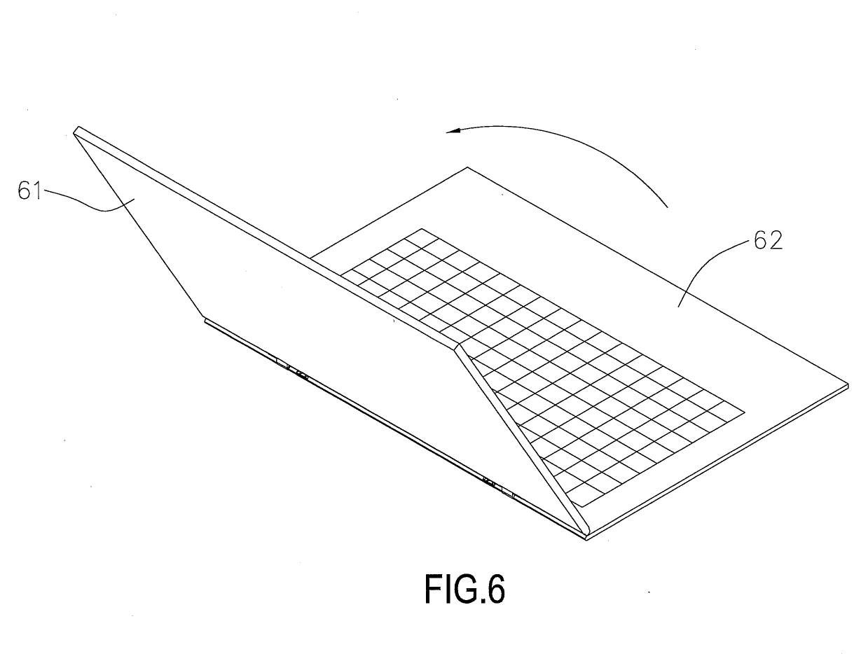

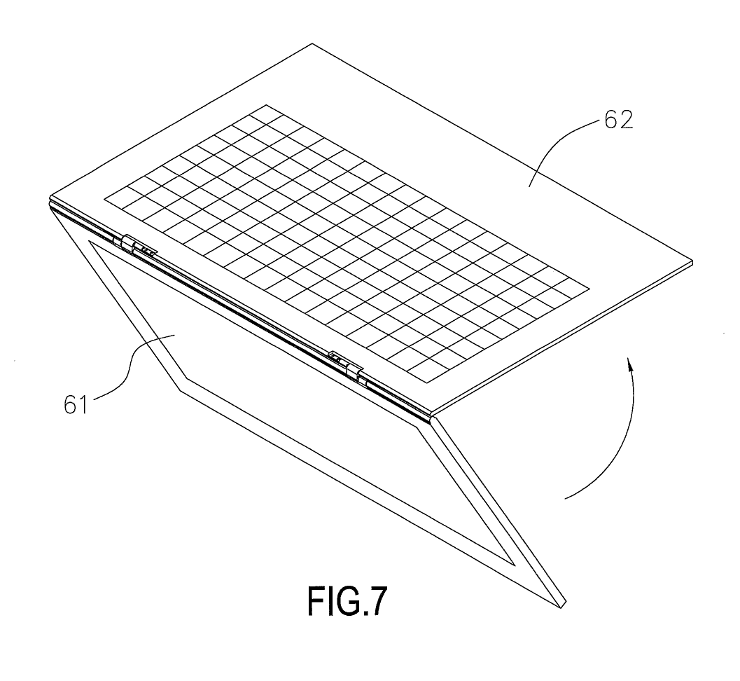

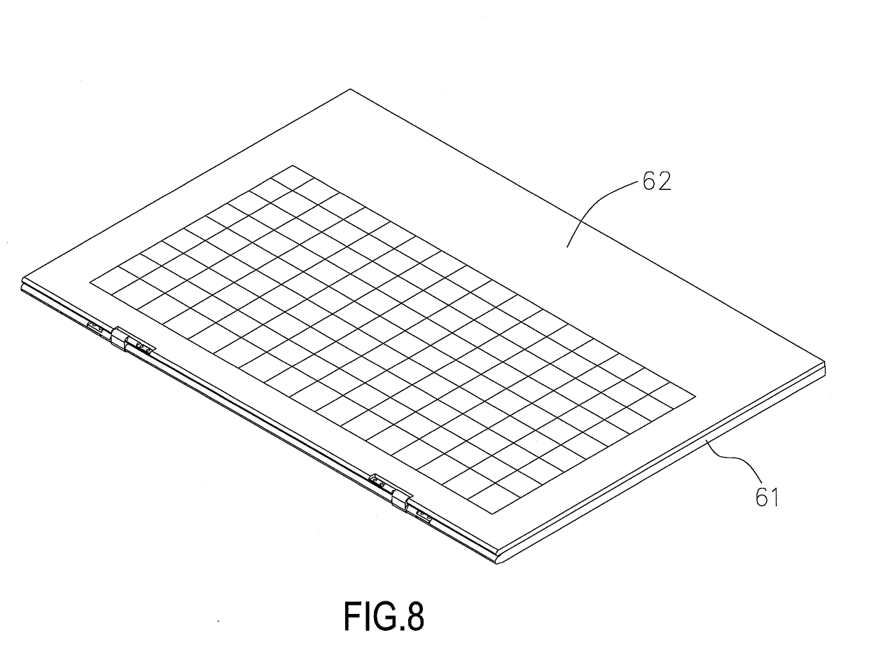

Referring to FIGS. 5, 5A, 6, 7 and 8 which illustrate the perspective views of the present invention for an electronic device in different embodiments: the electronic device comprises a first device body 61, a second device body 62, supports 63 inside the device bodies and the hinge hereinbefore; the hinge is installed to and fixed on the supports 63 of the electronic device. In the course of the first device body 61 on the electronic device turned and opened by one user, the first connecting part 3 is driven simultaneously for the first device body 61 freely turned to an angle. When the stopper 31 of the first connecting part 3 is held and restricted by the retainer 22, the first device body 61 has been turned to the maximum angle. Next, the first device body 61 can be turned continuously to further drive the second shaft 4 of the twin-shaft body 1 until the first device body 61 over the second device body 62. When the stopper 51 of the second connecting part 5 is held and restricted by the retainer 42 of the second shaft 4, the device body has reached the maximum turning angle.

It can be seen from the said structure that the present invention provided with a twin-shaft device embodies not only a general application for one electronic device but also the turned first device body 61 over the second device body 62 for the first device body 61 overlapping the second device body 62 approximately and an electronic device's increased turning angle.

The said embodiments should be referred to as examples to explain principles and efficiency of the present invention only but do not restrict the present invention. Any person skilled in the art may make any correction or change to the embodiments without departing from technical principles and spirit of the present invention.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A hinge, which is used in supports on an electronic device, comprising:
a twin-shaft body provided with at least one mounting hole;
a first shaft having one end inserted into the mounting hole of the twin-shaft body and the other extended end with a pivot part and a retainer on the shaft;
a first connecting part having one end with a pivot hole used to be coupled with the first shaft's pivot part, which corresponds to a stopper engaged and held by the retainer, and the other end with a holder on which there is one connecting hole used to link a support of an electronic device;
a second shaft having one end inserted into the mounting hole of the twin-shaft body and the other extended end with a pivot part and a retainer on the shaft;
a second connecting part having one end with a pivot hole used to be coupled with the second shaft's pivot part, which corresponds to a stopper engaged and held by the retainer, and the other end with a holder on which there is one connecting hole used to link a support of an electronic device.

2. The hinge according to claim 1 wherein the ladder-like mounting hole on the twin-shaft body comprises a deformed mounting hole and a pilot hole interlinking the deformed mounting hole.

3. The hinge according to claim 1 wherein the pivot part on the first shaft is designed to have a plurality of lubricant grooves for lubricant accommodated.

4. The hinge according to claim 2 wherein the first shaft's one end is a locator which is inserted into a mounting hole and a pilot hole in the twin-shaft body and a check surface is developed between the retainer and the locator.

5. The hinge according to claim 1 wherein the second shaft has a pivot part on which there are a plurality of lubricant grooves for lubricant accommodated.

6. The hinge according to claim 2 wherein the second shaft has one end with a locator which is inserted into a mounting hole and a pilot hole in the twin-shaft body and a check surface is developed between the retainer and the locator.

7. An electronic device with the hinge, comprising:
a first device body and a support inside the first device body;
a second device body and a support inside the second device body; and
the hinge according to claim 1 wherein the hinge links both the supports in first device body and the second device body and the supports correspond to the first device body and the second device body for turning.
